(19) United States
(12) Patent Application Publication
(10) Pub. No.: US 2010/0213532 A1
(43) Pub. Date: Aug. 26, 2010

(54) SEMICONDUCTOR DEVICES

(76) Inventors: Yoshiki KAMATA, Tokyo (JP); Yuuichi Kamimuta, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/706,319

(22) Filed: Feb. 16, 2010

(30) Foreign Application Priority Data
Feb. 25, 2009 (JP) 2009-042465

(51) Int. Cl. H01L 29/788; H01L 27/092; H01L 29/06

(52) U.S. Cl. 257/316; 257/369; 257/347; 257/E27.062; 257/E29.3; 257/E29.02

(57) ABSTRACT

A semiconductor device is provide, which includes a semiconductor region containing Ge as a major component, an insulating film formed on the semiconductor region, and a metallic film formed on the insulating film. At least a portion of the insulating film in contact with the semiconductor region is constituted by an oxide containing at least one rare-earth element M_{R} and at least one Group IV element M_{IV} selected from Ti and Zr.

### CROSS-REFERENCE TO RELATED APPLICATIONS

This application is based upon and claims the benefit of priority from prior Japanese Patent Application No. 2009-042465, filed Feb. 25, 2009, the entire contents of which are incorporated herein by reference.

### BACKGROUND OF THE INVENTION

1. Field of the Invention

This invention relates to a semiconductor device.

2. Description of the Related Art

Although a silicon single crystal substrate has been conventionally employed as a substrate for a semiconductor device, a germanium substrate is now attracting much attention because the mobility of electrons and holes is greater than that of silicon. Meanwhile, in order to reduce the film thickness equivalent to SiO₂ (equivalent oxide thickness: EOT), a deposition film containing a high-k material is now increasingly employed as a gate insulating film of the transistor, thus substituting for the conventional thermal oxide film.

The EOT of the insulating film of a Ge MOS device is about 0.5 nm. Since the dielectric constant of Ge oxide is about 10 at most, it is indispensable, in the new generation where a Ge MOS device is to be employed, to employ a high-k material which does not form a low-dielectric-constant interfacial layer such as those containing Ge oxide as a major component.

With respect to the Ge field-effect transistor (FET), it has been reported that an LaAlO₃/Ge gate stack structure exhibits excellent FET characteristics as demonstrated, for example, by Yu, D. S., et al. (Tech. Dig. Int. Electron Devices Meet (2004)). Further, in Afanas'ev, V. V., et al., Appl. Phys. Lett. (2006) 88, 132111, there is described a report of the band alignment in the LaHfOₓ/Ge gate stack structure.

### BRIEF SUMMARY OF THE INVENTION

A semiconductor device according to one aspect of the present invention comprises a semiconductor region comprising Ge as a major component; an insulating film formed on the semiconductor region, at least a portion of the insulating film in contact with the semiconductor region being constituted by an oxide comprising at least one rare-earth element M_{R} and at least one Group IV element M_{IV} selected from Ti and Zr; and a metallic film formed on the insulating film.

A semiconductor device according to another aspect of the present invention comprises a flash memory comprising a floating gate, a control gate and an insulating film sandwiched between the floating gate and the control gate, at least one of the floating gate and the control gate comprising Ge as a major component, and at least a portion of the insulating film in contact with the gate comprising Ge being constituted by an oxide comprising at least one rare-earth element M_{R} and at least one Group IV element M_{IV} selected from Ti and Zr. A semiconductor device according to a further aspect of the present invention comprises an insulator; a semiconductor region comprising Ge as a major component and formed unidirectionally on the insulator; source and drain regions formed at the opposite end portions of the semiconductor region; a gate insulating film formed at least on both sidewalls of the semiconductor region sandwiched between the source and drain regions, at least a portion of the gate insulating film in contact with the semiconductor region being constituted by an oxide comprising at least one rare-earth element M_{R} and at least one Group IV element M_{IV} selected from Ti and Zr; and a gate electrode formed on the gate insulating film.

### BRIEF DESCRIPTION OF THE SEVERAL VIEWS OF THE DRAWING

FIG. 1 is a graph illustrating the CV characteristics of a TiO₂/Ge MOS capacitor;

FIG. 2 is a ternary diagram of Ti—Si—O;

FIG. 3 is a ternary diagram of Ti—Ge—O;

FIG. 4 is a TEM photograph showing a cross-section of an La₂Ti₂O₇ (LTO)/Ge gate stack;

FIG. 5 is an La profile taken along the depthwise direction of an LTO/Ge stack;

FIG. 6 is a Ti profile taken along the depthwise direction of an LTO/Ge stack;

FIG. 7 is a Ge profile taken along the depthwise direction of an LTO/Ge stack;

FIG. 8 is an O profile taken along the depthwise direction of an LTO/Ge stack;

FIG. 9 is a diagram showing the structure of a MOS device according to one embodiment;

FIG. 10 is a graph illustrating the CV characteristics of an LTO/Ge MOS capacitor;

FIG. 11 is a cross-sectional view illustrating a semiconductor device according to another embodiment;

FIG. 12 is a cross-sectional view illustrating a semiconductor device according to a further embodiment;

FIG. 13 is a bird's-eye view schematically showing the structure of a semiconductor device according to a further embodiment;

FIG. 14 is a cross-sectional view illustrating the semiconductor device shown in FIG. 13;

FIG. 15 is a cross-sectional view illustrating the semiconductor device shown in FIG. 13;

FIG. 16 is a TEM photograph showing a cross-section of an La₂Zr₂O₇ (LZO)/Ge gate stack;

FIG. 17 is an La profile taken along the depthwise direction of an LZO/Ge stack;

FIG. 18 is a Zr profile taken along the depthwise direction of an LZO/Ge stack;

FIG. 19 is a Ge profile taken along the depthwise direction of an LZO/Ge stack;

FIG. 20 is an O profile taken along the depthwise direction of an LTO/Ge stack;

FIG. 21 is a graph illustrating the CV characteristics of an LZO/Ge MOS capacitor;

FIG. 22 is an La profile taken along the depthwise direction of a LHO/Ge stack;

FIG. 23 is a Hf profile taken along the depthwise direction of a LHO/Ge stack;

FIG. 24 is a Ge profile taken along the depthwise direction of a LHO/Ge stack; and

FIG. 25 is an O profile taken along the depthwise direction of a LHO/Ge stack.

### DETAILED DESCRIPTION OF THE INVENTION

Embodiments will be explained as follows.

In an attempt to create an insulating film excellent in electrical characteristics on the substrate comprising Ge as a major component, many studies have been extensively performed by the present inventors.

In this specification, the expression of “comprising Ge as a major component” means that the content of Ge in the substrate is 85 at. % or more. For example, there is a report in Semicond. Sci. Technol.

12(1997) 1515-1549 saying that when the minimum value of the conduction band of Si is defined by Δ point and the minimum value of the conduction band of Ge is defined by L point, these points vary depending on the composition ratio of SiGe. Namely, when the composition of SiGe is defined by SiₓGe₁₋ₓ, the minimum value would become Δ point under the condition of x<0.85 or L point under the condition of x>0.85.

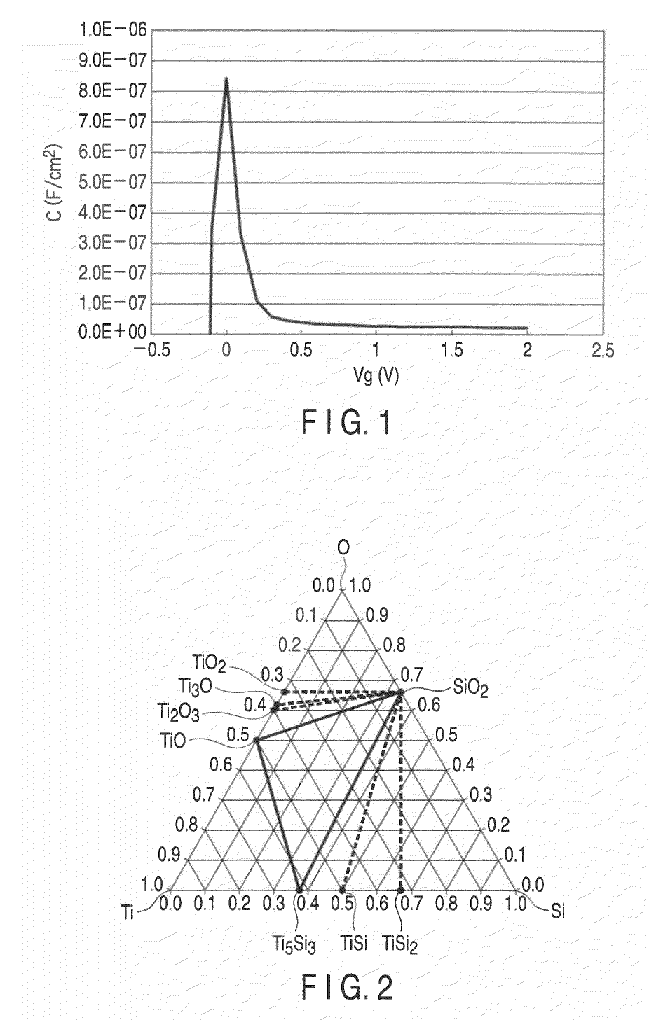

It has been found out by the present inventors that when a TiO₂ film is formed as an insulating film on the substrate containing Ge as a major component, the resultant insulating film would be low in barrier properties. As shown in FIG. 1, it is impossible to measure the CV characteristics. When a ZrO₂ film is formed on the same kind of substrate, Ge diffuses into the film.

In an attempt to create a gate stack structure excellent in electrical characteristics on the substrate containing Ge as a major component, many studies have been extensively performed by the present inventors. As a result, it has been found out that an oxide film containing, in addition to Ti or Zr, a rare-earth element especially La is the most suitable for use.

With respect to the dielectric constant of a ferroelectric film containing La, the following facts have been found out by the present inventors.

First of all, an Si substrate was treated with a mixed solution comprising sulfuric acid and an aqueous hydrogen peroxide solution and then pre-treated using dilute hydrofluoric acid. Then, an insulating film consisting of an LTO film was deposited to a thickness of about 100 nm on the pre-treated Si substrate. The resultant Si substrate was then subjected to an annealing for 30 minutes in a nitrogen atmosphere at a predetermined temperature. After this annealing, electrodes were formed, through a SUS mask, on the Si substrate to create a MOS capacitor.

Further, by repeating the same procedures as described above except that an LZO film was substituted for the LTO film, another kind of MOS capacitor was created.

Then, the CV characteristics of these MOS capacitors were measured respectively to obtain data.

Furthermore, the film thickness of the insulating film of each of these MOS capacitors was measured by cross-sectional SEM observation. The dielectric constant of these insulating films was calculated based on the results of measurements. The dielectric constant thus obtained is summarized in the following Table 1.

TABLE 1

| | Heat treatment temp. (° C.) | | |
|---|---|---|---|
| | 400 | 500 | 600 |
| LTO | 24 | 25 | 28 |
| LZO | 24 | 26 | 28 |

As the oxide containing La, there is known LaAlO₃ (LAO) having a dielectric constant of around 18. As shown in Table 1, the dielectric constant of both LTO and LZO is around 25 which is higher than that of LAO. The reason for this may be assumably attributed to the fact that the dielectric constant of TiO₂ and ZrO₂, both being a mother phase of LTO and LZO respectively, is higher than that of Al₂O₃, and hence this higher dielectric constant is reflected therein.

TiO₂ includes a crystal phase having a dielectric constant of 40-80 or so. The dielectric constant shown in above Table 1 represents the results obtained from the annealing of LTO at a temperature of 500° c and the features of the film was assumed as being amorphous. When the dielectric constant of the mother phase La₂O₃, which is around 20, is taken into account, the result that the dielectric constant of LTO was found as being around 25 is understandable.

It should be noted that Ti oxides such as TiO₂ are poor in stability on the Si substrate, resulting in the formation of Ti silicide. This phenomenon can be estimated from the thermal stability of the ternary system of Ti—Si—O as described, for example, in Beyer, R., J. Vac. Sci. Technol. B2 781 (1984). Herein, the thermal stability of the ternary system of Ti—Si—O will be explained with reference to the ternary diagram of FIG. 2. FIG. 2 indicates that since a tie line can be drawn between SiO₂ and Ti₅Si₃, a tie line cannot be drawn between Ti oxides and Si. Therefore, it is possible to expect that Ti oxides are poor in thermal stability on the Si substrate.

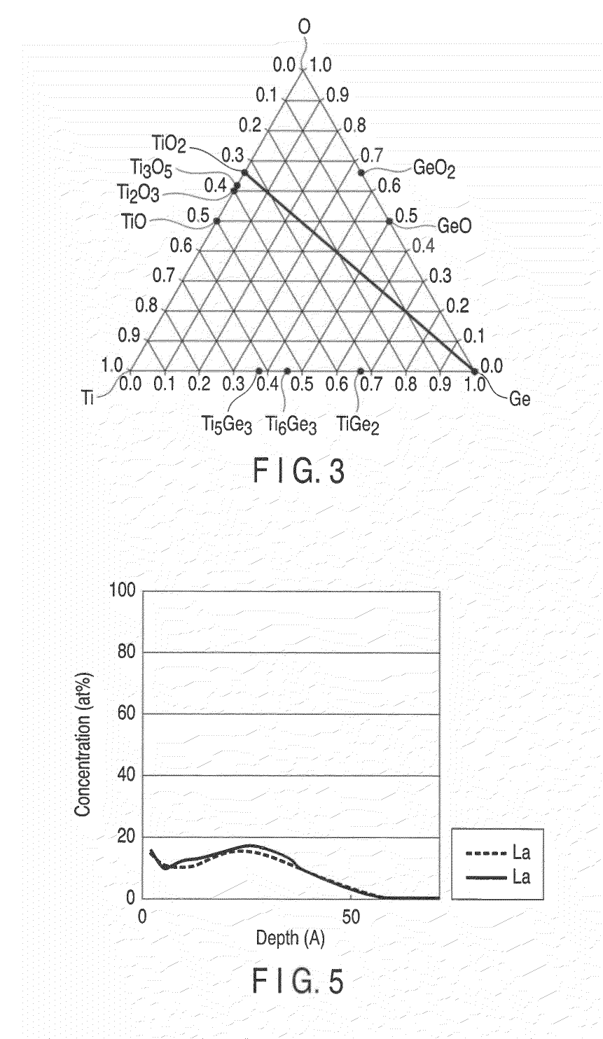

As explained below in detail, it is possible to draw a tie line between Ti oxides and Ge as shown in FIG. 3. It has been found out by the present inventors that although Ti oxides are poor in thermal stability on the Si substrate as explained above, Ti oxides behave in a different manner on the Ge substrate from that on the Si substrate. In the following Table 2, Gibbs free energy at 1000K is summarized. This 1000K is required on the occasion of discussing the tie lines in FIGS. 2 and 3.

TABLE 2

| Compounds | −ΔG₁₀₀₀ (kcal/mol) |
|---|---|
| TiO₂ | 739.5 |
| SiO₂ | 726.9 |
| TiSi₂ | 127.6 |
| GeO₂ | 397.1 |
| GeO | 105.7 |
| TiGe₂ | — |
| Ti₅Ge₆ | — |

As shown in above Table 2, the −ΔG₁₀₀₀ of TiO₂ and SiO₂ is 739.5 kcal/mol and 726.9 kcal/mol, respectively, i.e. almost the same with each other. Meanwhile, in the case of Ge oxides, as compared with the −ΔG₁₀₀₀ of TiO₂ and SiO₂, the −ΔG₁₀₀₀ of Ge oxides is very small, thus indicating that Ge oxides are thermally instable.

Table 3 shown below denotes Gibbs free energy balance before and after a reaction such as a silicification reaction.

TABLE 3

| Reaction | −ΔG₁₀₀₀ (kcal/mol) |
|---|---|
| TiO₂ + 3Si = TiSi₂ + SiO₂ | −115 |
| TiO₂ + 3Ge = TiGe₂ + GeO₂ | 342.4 +ΔG₁₀₀₀(TiGe₂) |
| TiO₂ + 4Ge = TiGe₂ + 2GeO | 528.1 +ΔG₁₀₀₀(TiGe₂) |
| TiO₂ + 1⅕Ge = ⅕Ti₅Ge₆ + GeO₂ | 342.4 +⅕ΔG₁₀₀₀(Ti₅Ge₆) |

In order to draw a tie line in the ternary diagram as shown in FIG. 2 or FIG. 3, Gibbs free energy balance before and after a reaction is employed. In order to create GeO₂ and Ti germanide (TiGeₓ) through the reaction between TiO₂ and Ge, the value of −ΔG₁₀₀₀ of Ti germanide is required to be fairly large. Namely, it is expected that unless Ti germanide is fairly stable, the reaction between TiO₂ and Ge can hardly take place.

It is reported by Aldrich, D. B., et al. in Phys. Rev. B (1996) 53, 16279 that when SiGe is reacted with Ti, Ti silicide is more liable to be created rather than Ti germanide. It may be said that Ti silicide is more stable than Ti germanide, i.e. −ΔG_{1000(TiGe2)}<127.6 (kcal/mol)=−ΔG_{1000(TiSi2)}. Therefore, the Gibbs free energy balance of right side in the reaction for creating the TiGe₂ of Table 3 becomes positive. It is assumed that the reaction cannot move rightward and hence TiGe₂ cannot be created, thus making it possible to draw a tie line between Ti oxides and Ge as shown in FIG. 3.

It should be noted that the CV hysteresis (ΔVfb) in a MOS capacitor which can be obtained from an Si substrate provided thereon with an LTO insulating film having a thickness of 100 nm or so may be 3.3-3.5 V or so, provided that the temperature of annealing to be applied thereto is 400-500° c. When this LTO is replaced by LAO, LZO or LHO under the same conditions, the value of ΔVfb would be less than 0.5 V.

The fact that the value of ΔVfb of LTO is considerably large as compared with other oxides may represent one example indicating thermal instability of Ti oxides and Si.

It has been found out from these results that LTO and LZO may exhibit more excellent electrical properties compared to LAO on the substrate containing Ge as a major component.

Next, embodiments will be specifically explained with reference to drawings.

### First Embodiment

First of all, a Ge wafer was subjected to an acetone treatment to execute the defatting thereof and the removal of organic substances. Then, the treated Ge wafer was washed with a mixed solution comprising hydrochloric acid (20%) and an aqueous hydrogen peroxide solution (0.1%) to remove metallic contaminents. The Ge wafer thus washed was allowed to dry to accomplish the pre-treatment thereof.

On this pre-treated Ge wafer was deposited La₂Ti₂O₇ (LTO) by pulse laser deposition (PLD) method. After finishing the deposition of the LTO, the Ge wafer was subjected to post deposition annealing (PDA) in a nitrogen atmosphere for 30 minutes at a temperature of 500° c.

As shown in FIG. 4, it was possible to confirm the formation of an excellent LTO/Ge substrate interface. The band gap (Eg) thereof was 4.06 eV and no change was recognized in the measurements before and after the annealing. It should be noted that the band gap was calculated based on the measured spectrums obtained from reflection electron energy loss spectroscopy (REELS).

In order to create source/drain regions by a diffusion layer formed using a conductive impurity (dopant) in the manufacture of a high-k/Ge MOSFET, it is generally required to perform an annealing at a temperature of 500° c for activating the impurity. It has been confirmed from the aforementioned results that the 500° c annealing has very little influence on the Eg and that the LTO has a sufficient Eg for the formation of a high-k/Ge MOSFET.

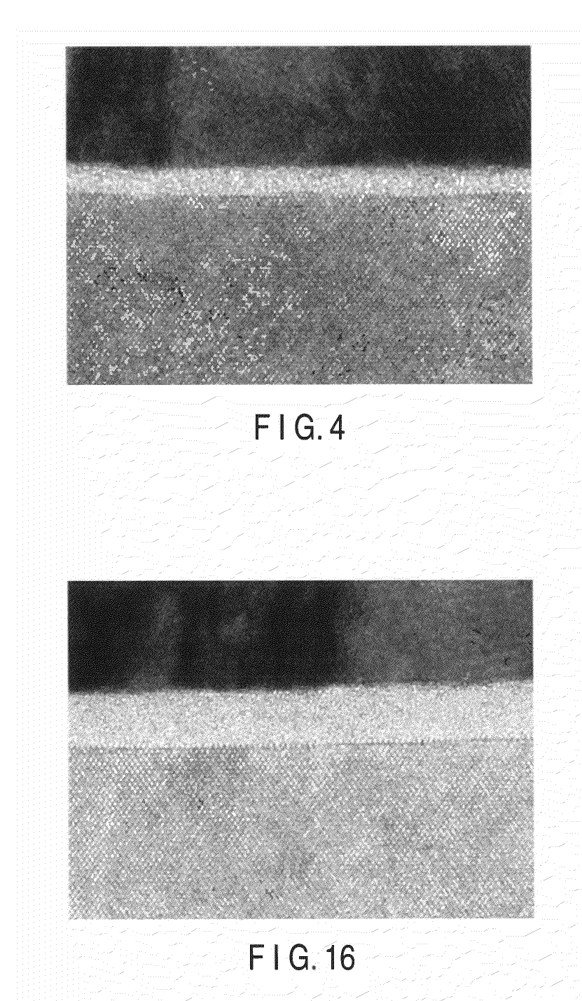

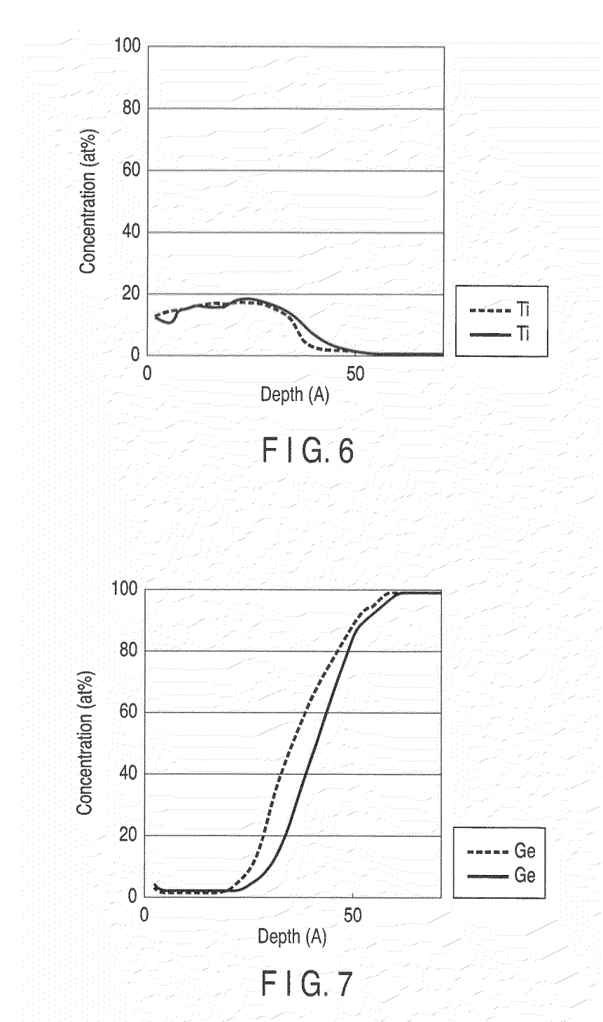

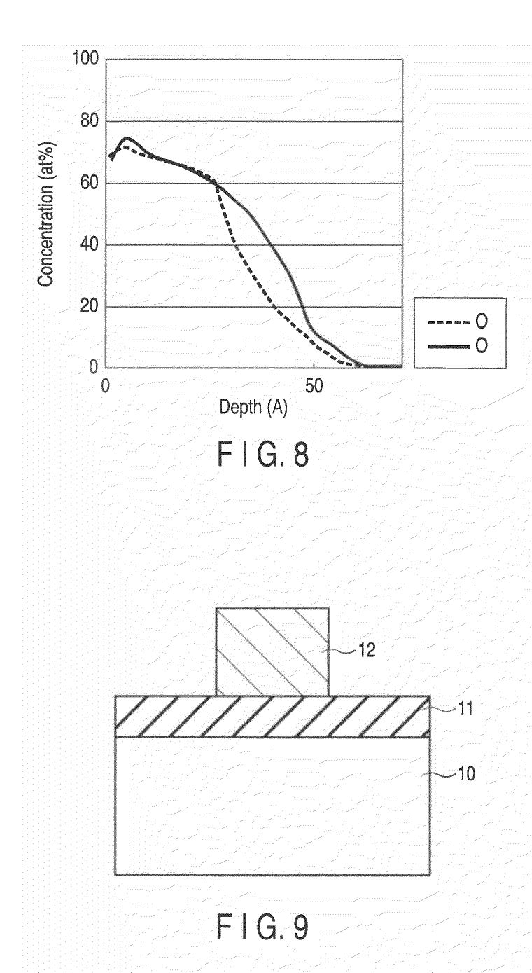

Further, the high-k/Ge gate stack structure thus obtained was investigated with respect to a depth profile of each element before and after the annealing (30 minutes in a nitrogen atmosphere at 500° c) by high-resolution Rutherford backscattering spectroscopy (HRBS), the results being shown in FIGS. 5-8. In every case of FIGS. 5-8, the dotted line indicates a profile before the annealing and the solid line indicates a profile after the annealing.

At the insulating film/Ge interface that had been heat-treated, there was recognized no fluctuation in the concentration of La and the concentration of Ge was caused to decrease. Further, it will be recognized from FIGS. 5-8 that the concentration of Ti as well as the concentration of O was caused to increase and the interface transition layer was reduced in thickness. In view of the facts that Ge oxides are thermally instable and Ti oxides are enabled to take various oxidized states, it may be conceivable that Ge oxides of low oxidation number was replaced by high-oxides containing Ti as a major component at the insulating film/Ge interface. Further, the fact that Ge was not contained in the LaTiO film is notable.

When Ge is contained in a high-k film, it may lead to the deterioration of electrical properties such as the deterioration of mobility due to charge trap, etc. In this connection, there is a report of Kamata, Y., et al. in Tech. Dig. Int. Electron Devices Meet (2005), 429, suggesting a presumption that the deterioration of mobility may be attributed to the generation of voids in the high-k film due to the existence of La having a large ionic radius. La has the largest ionic radius among the rare-earth elements. Therefore, in the case of the insulating film comprising Ti and another rare-earth element having a smaller ionic radius than La, it is possible to expect the inhibition of Ge diffusion into the high-k film.

Then, using a SUS mask, Pt was deposited on the LTO/Ge gate stack to create a MOS capacitor having a structure as shown in FIG. 9. In the MOS capacitor shown herein, a gate insulating film 11 of LTO and a gate electrode 12 of Pt are formed on the substrate 10 containing Ge as a major component. After the deposition of this Pt electrode, the resultant substrate was subjected to a annealing for 30 minutes in a nitrogen atmosphere at 500° c and then to a forming gas annealing (FGA) using N₂/H₂ for 30 minutes at 350° c.

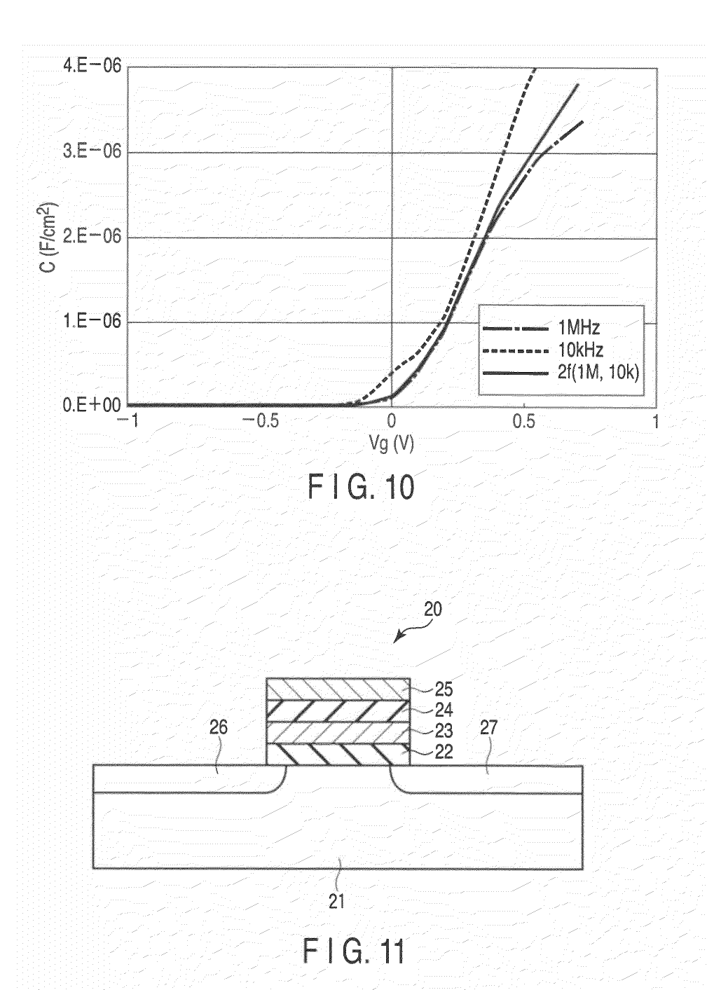

The MOS capacitor treated in this manner was measured with respect to the CV characteristics thereof at −50° c. The frequencies employed in this measurement were 1 MHz and 10 kHz. Additionally, on the basis of 1 MHz and 10 kHz, a dual-frequency correction was performed to calculate ideal CV characteristics. As shown in FIG. 10, it was possible to obtain excellent CV characteristics of EOT<1 nm.

The semiconductor device according to one embodiment can be made into a flash memory as shown in FIG. 11. In the semiconductor device shown in FIG. 11, a tunnel oxide film 22, a floating gate 23, an interpoly insulating film 24 and a control gate 25 are successively deposited on the device regions of the substrate 21. In two regions of the substrate which are located below the opposite sides of the tunnel oxide film 22, a source region 26 and a drain region 27, both consisting of a high-impurity-concentration diffusion region, are formed, thereby creating a flash memory 20.

As the substrate 21, it is possible to employ an Si substrate, an SₓGe₁₋ₓ substrate (x=0 to 1) or a Ge substrate. These substrates may contain a suitable amount of C or may be respectively formed of a substrate on an insulating film such as silicon-on-insulator (SOI).

The interpoly insulating film 24 can be constituted by a high-k insulating film containing at least one kind of rare-earth element (M_{R}) and at least one kind of Group IV element (M_{IV}) selected from Ti and Zr as already described above. At least one of the floating gate 23 and the control gate 25 is provided, on the interpoly insulating film 24 thereof, with a Ge semiconductor region. The interpoly insulating film 24 should preferably be directly contacted with the Ge semiconductor region without interposing an interface layer between the Ge semiconductor region and the interpoly insulating film 24.

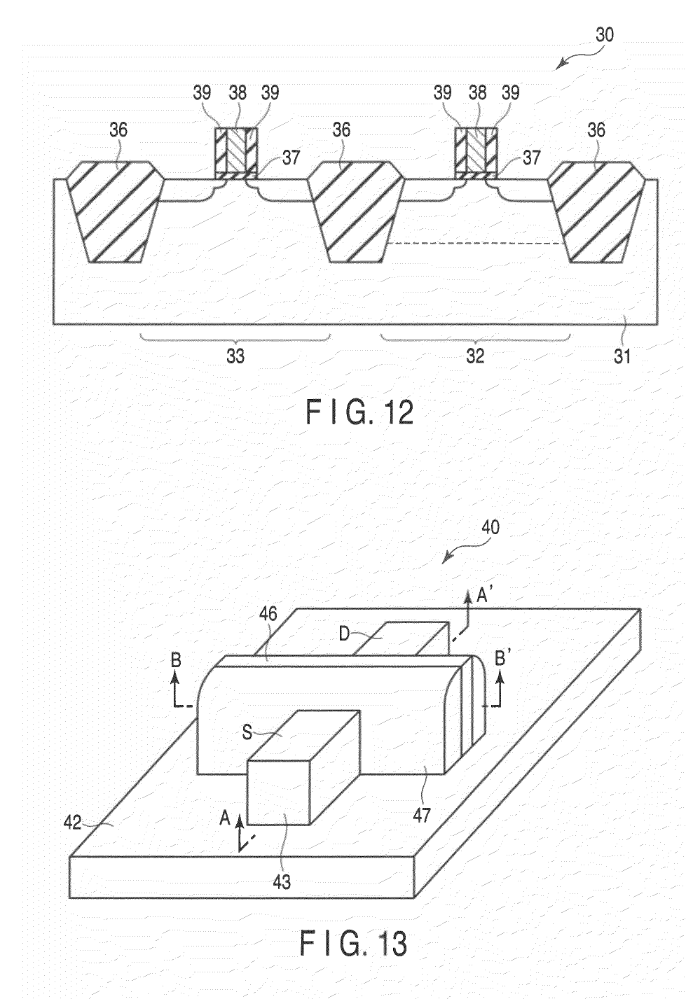

Further, the semiconductor device according to other embodiment may be made into a complementary MISFET as shown in FIG. 12. In the semiconductor device shown in FIG. 12, the device regions are delimited in an Si substrate 31 by an isolation region 36. In each of the device regions, a gate electrode 38 is formed thereon via a gate insulating film 37 and a gate sidewall insulating film 39 is formed on the opposite sidewalls of the gate electrode 38, thereby constructing a complementary MISFET 30. Although the source/drain regions are respectively formed of a high-impurity-concentration diffusion layer in this FIG. 12, the source/drain regions may be of course formed of Schottky source/drain regions using a metal electrode.

It should be noted that, although at least the device regions in a p-MISFET region 32 are required to contain Ge as a major component, the device regions in an n-MISFET region 33 may be also formed to contain Ge as a major component.

The gate insulating film 37 can be constituted by a high-k insulating film containing at least one kind of rare-earth element (M_{R}) and at least one kind of Group IV element (M_{IV}) selected from Ti and Zr as already described above. The gate insulating film 37 should preferably be directly contacted with the device regions containing Ge as a major component without interposing an interface layer between the device regions containing Ge as a major component and the gate insulating film 37.

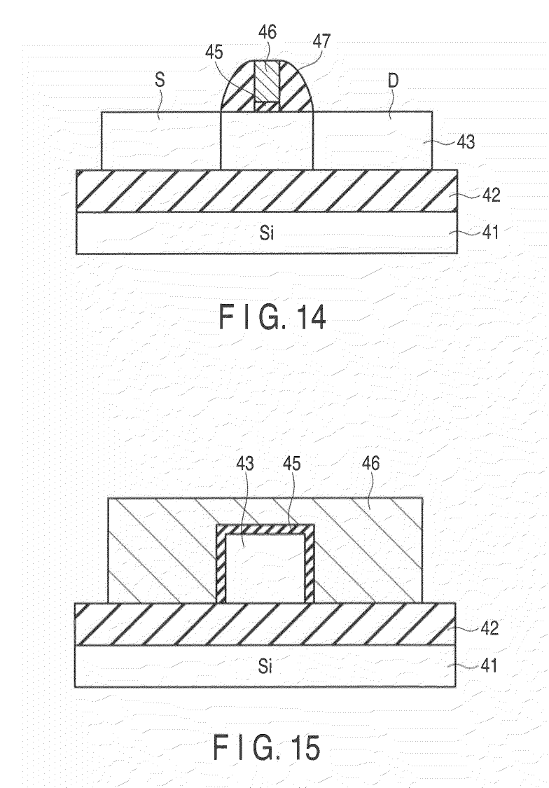

Further, the semiconductor device according to another embodiment may be made into a FinFET as shown in FIG. 13. FIG. 14 shows a cross-sectional view taken along arrow A-A′ of FIG. 13, and FIG. 15 shows a cross-sectional view taken along arrow B-B′ of FIG. 13.

On a buried insulating film 42 formed on the single crystal Si substrate 41, there is formed a fin-like Ge layer 43 having source/drain regions S, D. A gate insulating film 45 is formed so as to cover the upper surface of the central portion of the Ge layer 43 as well as the opposite sidewalls of the Ge layer 43. A gate electrode 46 is formed so as to cover this gate insulating film. This gate electrode 46 is extended so as to cover not only the gate insulating film 45 but also a portion of the insulating film 42. A gate sidewall insulating film 47 is formed on the opposite sidewalls of the gate electrode 46, thereby constructing a MISFET 40 having a fin-like structure.

It should be noted that, although the device shown in FIGS. 13-15 is directed to a tri-gate-type device wherein the top surface and the opposite sidewalls of the Ge layer are covered by a gate insulating film, it may be of course made into a double-gate-type device wherein the opposite sidewalls of the Ge layer are covered by a gate insulating film and the top surface of the Ge layer is covered by a nitride film. The gate insulating film 45 can be constituted by a high-k insulating film containing at least one kind of rare-earth element (M_{R}) and at least one kind of Group IV element (M_{IV}) selected from Ti and Zr as already described above. The gate insulating film 45 should preferably be directly contacted with the Ge layer 43 without interposing an interface layer between the Ge layer 43 and the gate insulating film 45.

In the semiconductor device according to this embodiment, a specific kind of insulating film is formed on the substrate containing Ge as a major component. Since the insulating film contained at least one kind of rare-earth element (M_{R}) represented by La, at least one kind of Group IV element (M_{IV}) selected from Ti and Zr, and oxygen, it was possible to obtain excellent electrical properties.

### Second Embodiment

The same kind of Ge wafer as employed in the aforementioned first embodiment was heat-treated in the same manner as described in the first embodiment.

On this treated Ge wafer was deposited La₂Zr₂O₇ (LZO) by the PLD method and then the resultant Ge wafer was subjected to the PDA in a nitrogen atmosphere for 30 minutes at a temperature of 500° c.

As shown in FIG. 16, it was possible to confirm the formation of an excellent LZO/Ge substrate interface even after the annealing of 500° c. The band gap (Eg) thereof was 5.23 eV and no change was recognized in the measurements before and after the annealing. As in the case of the first embodiment, in view of the fact that the 500° c annealing had very little influence on the Eg, the LZO was confirmed to exhibit a sufficient Eg for the formation of a high-k/Ge MOSFET.

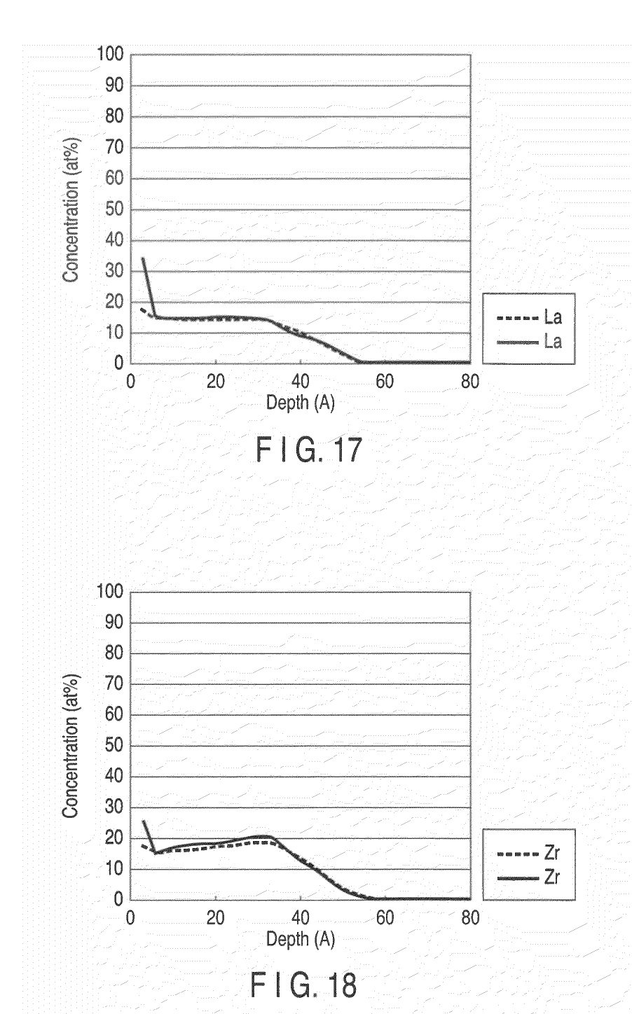

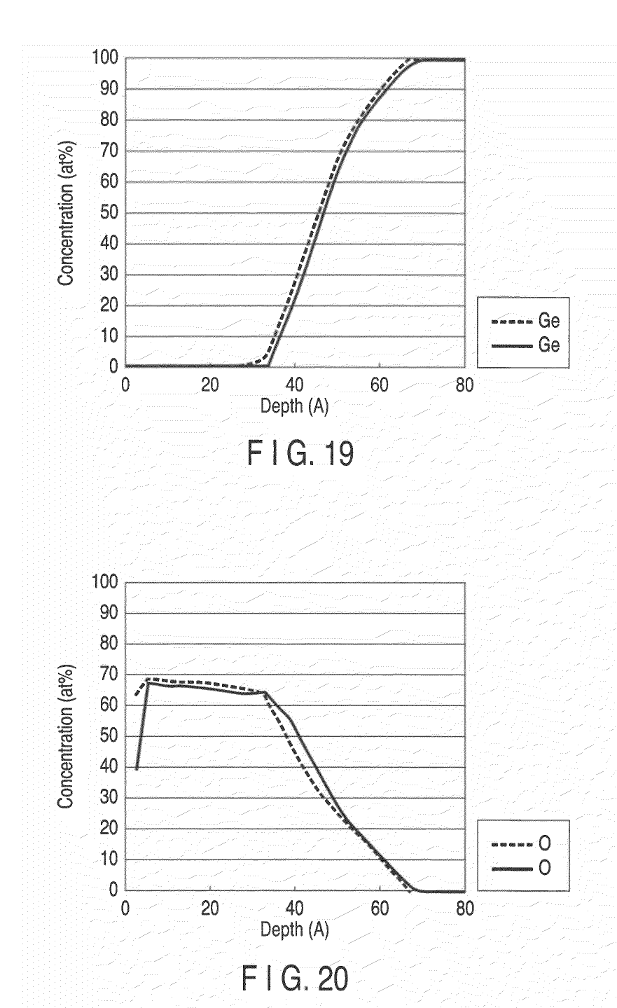

Further, the high-k/Ge gate stack structure thus obtained was investigated with respect to a depth profile of each element before and after the annealing by conducting the annealing in the same manner as described in the first embodiment, the results being shown in FIGS. 17-20.

In every case shown in FIGS. 17-20, the dotted line indicates a profile before the annealing and the solid line indicates a profile after the annealing. No fluctuation in the composition was recognized, indicating excellent gate stack integrity.

Further, the fact that Ge was not contained in the LaZrO film is notable. As described above, if Ge is contained in a high-k film, it may lead to the deterioration of electrical properties such as the deterioration of mobility due to charge trap, etc. As a result, the LaZrO film is conceivably capable of forming an excellent gate stack structure on the Ge substrate. Further, in the case of the insulating film comprising Zr and another rare-earth element having a smaller ionic radius than La, it is expected to ensure the inhibition of Ge diffusion into the high-k film due to the decrease of voids in the high-k film owing to the existence of rare-earth elements. Therefore, it is possible to expect excellent electrical properties.

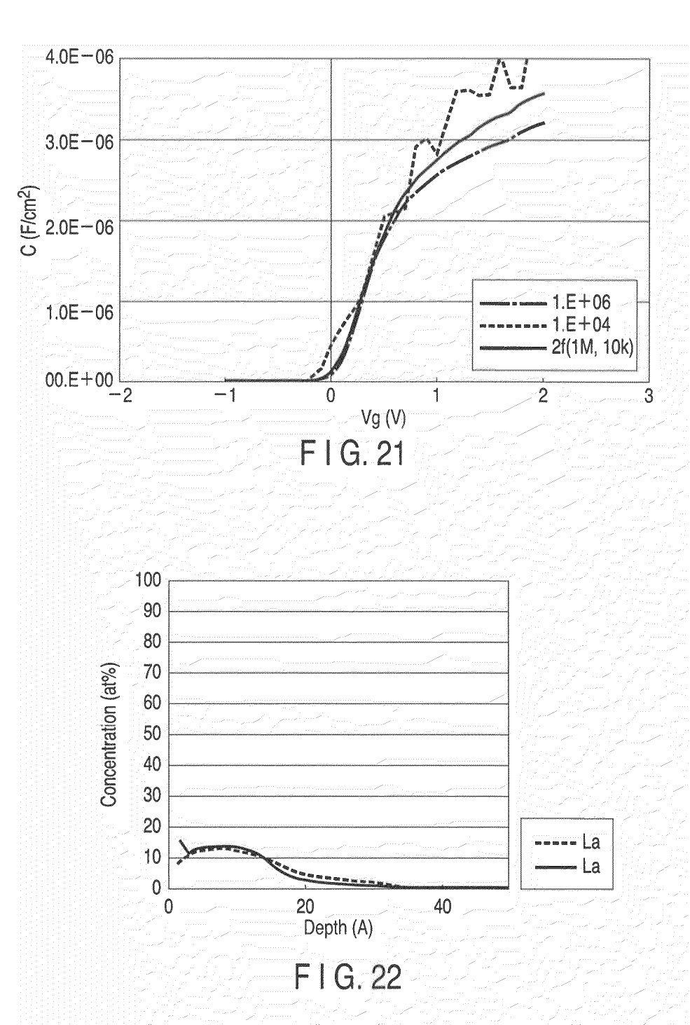

A MOS capacitor constructed as shown in FIG. 9 was formed by repeating the same procedures as described in the first embodiment except that the gate insulating film 11 was altered to an LZO film. The CV characteristics of the MOS capacitor which were determined after the annealing performed in the same manner as described above are shown in FIG. 21. As shown in FIG. 21, it was possible to obtain excellent CV characteristics of EOT<1 nm.

### Comparative Example

The same kind of Ge wafer as employed in the aforementioned first embodiment was pre-treated in the same manner as described in the first embodiment.

On this pre-treated Ge wafer was deposited La₂Hf₂O₇ (LHO) by the PLD method and then the resultant Ge wafer was subjected to the PDA in a nitrogen atmosphere for 30 minutes at a temperature of 500° c.

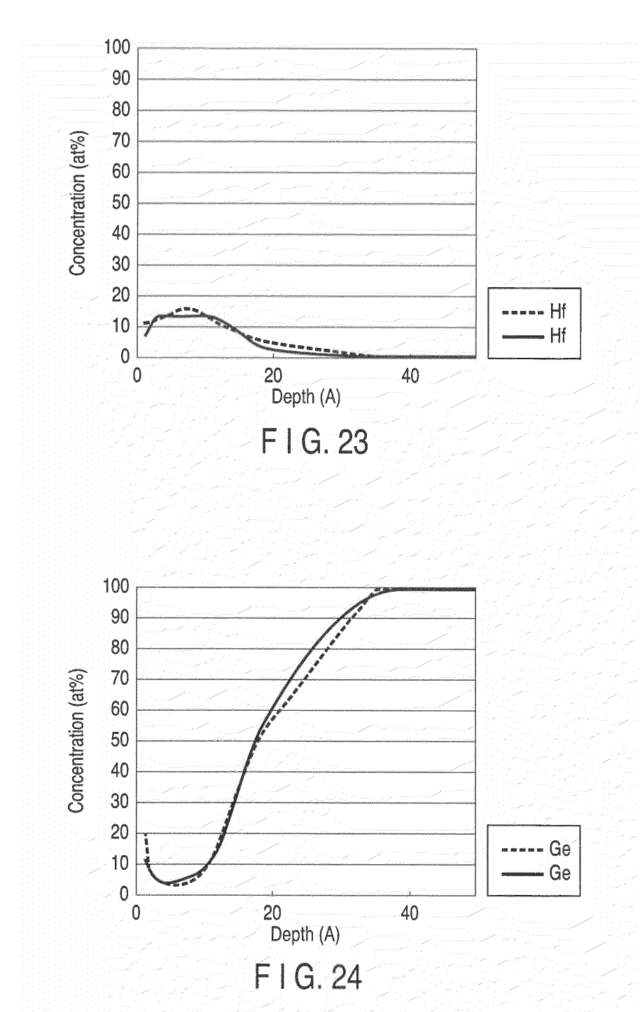

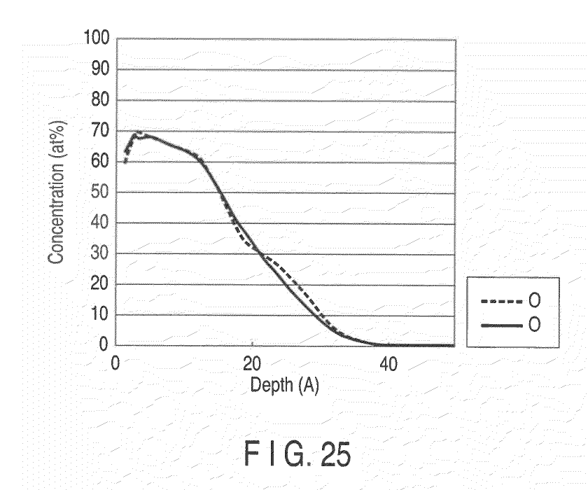

The high-k/Ge gate stack structure thus obtained was investigated with respect to a depth profile of each element before and after the annealing in the same manner as described in the first embodiment, the results being shown in FIGS. 22-25.

In every case shown in FIGS. 22-25, the dotted line indicates a profile before the annealing and the solid line indicates a profile after the annealing. Although the fluctuation of composition was not recognized before and after the annealing, the inclusion of Ge in the LHO film was recognized. As described above, if Ge is contained in a high-k film, it may lead to the deterioration of electrical properties such as the deterioration of mobility due to charge trap, etc. The reason for this may be attributed to the generation of voids in the high-k film due to the existence of La having a large ionic radius.

In the above embodiments, the element to be contained in the high-k film together with La was Ti or Zr. Therefore, any problem that may be brought about due to the existence of Hf can be avoided.

In the above embodiments, the explanation thereof was directed to the construction wherein a high-k film having a composition of La₂(M_{IV})₂O₇ was deposited on the Ge substrate. Herein, the composition of the target to be employed in the PLD was La₂ (M_{IV})₂O₇, and, due to the employment of this PLD, it was found possible to form a film having the same composition as that of the target.

Generally, the crystal of the La₂ (M_{IV})₂O₇ composition is most likely to take a pyrochlore structure. In the case of the pyrochlore structure, since the angle to be formed by M_{IV}-O-M_{IV} bond is 110-130°, the component of the d-orbit of an M_{IV} atom that may overlap therewith through the p-orbit of an O atom is relatively small, thereby making it possible to obtain excellent insulating properties.

The amorphous film having a composition of La₂ (M_{IV})₂O₇ is also expected to locally exhibit insulating properties at the pyrochlore crystal, so that when fine crystals are locally formed because of the annealing, it is possible to expect excellent insulating properties likewise. The pyrochlore crystal may be formed not only of (M_{R})₂(M_{IV})₂O₇ but also whereby part of the M_{R} site thereof is replaced by an M_{IV} atom. Further, the M_{IV} atom may not be limited to one kind but may include two kinds of atoms. In the case of the high-k film having such a composition, it is also expected, in view of the aforementioned discussion, to realize excellent insulating properties as described above.

According to the embodiments of the present invention, it is possible to provide a semiconductor device having a high-k film/Ge gate stack structure exhibiting excellent electrical properties.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor region comprising Ge as a major component;
an insulating film formed on the semiconductor region, at least a portion of the insulating film in contact with the semiconductor region being constituted by an oxide comprising at least one rare-earth element M_{R} and at least one Group IV element M_{IV} selected from Ti and Zr; and
a metallic film formed on the insulating film.

2. The semiconductor device according to claim 1, wherein the oxide has a composition represented by (M_{R})₂(M_{IV})₂O₇.

3. The semiconductor device according to claim 1, wherein the M_{R} is La.

4. The semiconductor device according to claim 1, wherein the M_{IV} is Ti.

5. The semiconductor device according to claim 1, wherein the M_{IV} is Zr.

6. A semiconductor device according to claim 1, wherein the semiconductor device comprises a p-type MISFET comprising the insulating film and the metallic film, formed in the semiconductor region formed on a Si substrate.

7. The semiconductor device according to claim 6, wherein the oxide has a composition represented by (M_{R})₂(M_{IV})₂O₇.

8. The semiconductor device according to claim 6, wherein the M_{R} is La.

9. The semiconductor device according to claim 6, wherein the M_{IV} is Ti.

10. The semiconductor device according to claim 6, wherein the M_{IV} is Zr.

11. The semiconductor device according to claim 6, wherein the semiconductor device is a complementary MISFET further comprising an n-type MISFET formed on the Si substrate; wherein the n-type MISFET comprises a device region comprising Ge as a major component and delimited by an isolation region, source and drain regions formed in the device region, a gate insulating film formed on the device region, and a gate electrode formed on the gate insulating film, at least a portion of the gate insulating film in contact with the device region being constituted by an oxide comprising at least one rare-earth element M_{R} and at least one Group IV element M_{IV} selected from Ti and Zr.

12. A semiconductor device comprising:
a flash memory comprising a floating gate, a control gate and an insulating film sandwiched between the floating gate and the control gate, at least one of the floating gate and the control gate comprising Ge as a major component, and at least a portion of the insulating film in contact with the gate comprising Ge being constituted by an oxide comprising at least one rare-earth element M_{R} and at least one Group IV element M_{IV} selected from Ti and Zr.

13. The semiconductor device according to claim 12, wherein the M_{R} is La.

14. The semiconductor device according to claim 12, wherein the M_{IV} is Ti.

15. The semiconductor device according to claim 12, wherein the M_{IV} is Zr.

16. A semiconductor device comprising:
an insulator;
a semiconductor region comprising Ge as a major component and formed unidirectionally on the insulator;
source and drain regions formed at the opposite end portions of the semiconductor region;
a gate insulating film formed at least on both sidewalls of the semiconductor region sandwiched between the source and drain regions, at least a portion of the gate insulating film in contact with the semiconductor region being constituted by an oxide comprising at least one rare-earth element M_{R} and at least one Group IV element M_{IV} selected from Ti and Zr; and
a gate electrode formed on the gate insulating film.

17. The semiconductor device according to claim 16, wherein the M_{R} is La.

18. The semiconductor device according to claim 16, wherein the M_{IV} is Ti.

19. The semiconductor device according to claim 16, wherein the M_{IV} is Zr.
